(19) United States
(12) Patent Application Publication
(10) Pub. No.: US 2007/0269908 A1
(43) Pub. Date: Nov. 22, 2007

(54) METHOD FOR IN-LINE CONTROLLING HYBRID CHEMICAL MECHANICAL POLISHING PROCESS

(76) Inventors: Hsin-Kun Chu, Kaohsiung County (TW); Yen-Chu Chen, Nantou County (TW); Teng-Chun Tsai, Hsin-Chu City (TW); Chia-Hsi Chen, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/383,761

(22) Filed: May 17, 2006

(51) Int. Cl. H01L 21/66

(52) U.S. Cl. 438/14

(57) ABSTRACT

A hybrid CMP system having a first platen and a second platen is provided. Two types of polish pads are mounted on the first platen and second platen. A lot of pattern wafers is prepared. Each pattern wafer has patterned features, and a first dielectric layer is disposed over a second dielectric layer and the patterned features. At least three foregoing pattern wafers of the lot are sequentially polished on the first platen to remove different amount of the first dielectric layer. Removal amount of each said foregoing pattern wafer is in-line measured and calculated to output a linear fitting curve of removal amount vs. polish time thereof. Based on the linear fitting curve, the rest of the pattern wafers of the same lot are sequentially polished on the first platen to reach a target thickness of remaining said first dielectric layer.

### BACKGROUND OF THE INVENTION

1. Field of the Invention

The present invention relates in general to a chemical mechanical polishing (CMP) process. More particularly, the present invention relates to a method of in-line controlling a hybrid CMP process for forming shallow trench isolation structure, which is capable of reducing the cost, simplifying the manufacturing process and increasing the throughput thereof.

2. Description of the Prior Art

Reliably producing sub-half micron and smaller features is one of the key technologies for the next generation of ultra large-scale integration (ULSI) of semiconductor devices. However, the shrinking dimensions of interconnect in ULSI technology have placed additional demands on the processing capabilities. The multilevel interconnects that lie at the heart of this technology require precise processing of high aspect ratio features. Reliable formation of these interconnects is important to ULSI success and to the continued effort to increase circuit density and quality of individual substrates and die.

Multilevel interconnects are formed by the sequential deposition and removal of materials from the substrate surface to form features therein. As layers of materials are sequentially deposited and removed, the uppermost surface of the substrate may become non-planar across its surface and require planarization prior to further processing. Planarizing a surface, or “polishing” a surface, is a process where material is removed from the surface of the substrate to form a generally even, planar surface. Planarization is useful in removing excess deposited material and in removing undesired surface topography and surface defects, such as rough surfaces, agglomerated materials, crystal lattice damage, scratches, and contaminated layers or materials to provide an even surface for subsequent processing.

Chemical mechanical polishing (CMP) is a common technique used to planarize substrates. In conventional CMP techniques, a substrate carrier or polishing head is mounted on a carrier assembly and positioned in contact with a polishing media in a CMP apparatus. The carrier assembly provides a controllable pressure to the substrate urging the substrate against the polishing media. The substrate and polishing media are moved in a relative motion to one another.

Chemical mechanical polishing may be used in the fabrication of shallow trench isolation (STI) structures, which separate transistors and components of a transistor, such as source/drain junctions or channel stops, on a substrate surface during fabrication. An example of a STI process includes depositing a silicon nitride layer on an oxide layer formed on a silicon substrate surface, patterning and etching the substrate surface to form a feature definition, depositing a silicon oxide fill of the feature definitions, and polishing the substrate surface to remove excess silicon oxide to form a feature. The silicon nitride layer may perform as a hard mask during etching of the features in the substrate and as a polishing stop during subsequent polishing processes. Such STI fabrication processes require polishing the silicon oxide layer to the silicon nitride layer with a minimal amount of silicon nitride removed during the polishing process in order to prevent damaging of the underlying materials, such as oxide and silicon.

The CMP process, in general, has the advantages of low cost, high removal rate and high uniformity efficiency. However, the disadvantage is that the selectivity of oxide to nitride is low and therefore the insufficient polishing or over-polishing of the oxide layer occurs, and thus requires an additional external process using a reserve mask (RM) to resolve this problem.

A hybrid CMP method using a high-selectivity-slurry (HSS) and a fixed-abrasive (FA) pad is developed to polish STI substrates. It is advantageous to use the hybrid CMP method during STI fabrication because the HSS pad has high selectivity to the trench fill material, while the FA pad can provide high uniformity for removing the remaining trench fill material without the fear of inducing dishing effects. According to the hybrid CMP method, a wafer is first polished on the first platen of a CMP tool using HSS slurry. The major polishing components in the HSS slurry include cerium oxide (CeO₂). The wafer is then transferred to the next platen (second platen) and polished with a FA pad. The major polishing particles of the fixed abrasive (FA) polishing method may also include cerium oxide.

In hybrid CMP process, it is critical to control the incoming oxide thickness on a wafer before the wafer is transferred to the second platen having the FA pad. The incoming oxide thickness control is particularly important for 300 mm FA web polish because so-called fast-band problem occurs resulting in narrow polish time window of the FA pad. Long polish time will lead to silicon nitride loss in fast-band areas, while short polish time will lead to residual oxide on non-fast band areas (typically central area of a wafer).

In order to control the incoming oxide thickness, one approach is using a blanket removal rate (RR) table established in advance by polishing a number of blanket wafers, each of which is polished using different polish time on the HSS pad and measured by using a thickness measurement tool. However, the removal rate of oxide dielectric on the blanket wafers polished by the HSS pad is not a constant, making it very difficult to determine the polish time on the HSS pad, therefore the control of the incoming oxide thickness before the FA pad becomes a major challenge. As shown in FIG. 1, the plot showing the removal amount vs. polish time with respect to a HSS pad indicates a poor correlation (H1, H2 referring to different HSS pads).

In light of the above, there is a need in this industry to provide a method for controlling the hybrid CMP process that can reduce the cost, improve the reliability, and increase the throughput and CMP process window.

### SUMMARY OF THE INVENTION

It is one object of the present invention to provide a method for polishing a STI substrate in order to improve the wafer production and to solve the above-mentioned problems.

One aspect of the invention provides a method for controlling hybrid chemical mechanical polishing (CMP) process. A hybrid CMP system having at least a first platen and a second platen is provided. Two different types of polish pads are mounted on the first platen and second platen, respectively. A lot of pattern wafers to be polished is prepared. Each pattern wafer has patterned features thereon, and a first dielectric layer is disposed over a second dielectric layer and the patterned features. At least three foregoing pattern wafers of the lot of pattern wafers are sequentially polished on the first platen to remove different amount of the first dielectric layer on each said foregoing pattern wafer. Removal amount of each said foregoing pattern wafer is in-line measured and calculated to output a substantially linear fitting curve of removal amount vs. polish time thereof. Based on the substantially linear fitting curve established by said foregoing pattern wafers, the rest of the pattern wafers of the same lot as said foregoing pattern wafers are sequentially polished on the first platen to reach a target thickness of remaining said first dielectric layer on each said pattern wafer.

In another aspect, a method is provided for controlling hybrid chemical mechanical polishing (CMP) process including providing a hybrid CMP system having at least a first platen and a second platen, wherein a high-selectivity slurry (HSS) pad and a fixed-abrasive (FA) pad are mounted on the first platen and second platen, respectively. A lot of pattern wafers to be polished is prepared, wherein each pattern wafer has patterned features thereon, and a first dielectric layer disposed over a second dielectric layer and the patterned features. The foregoing 3-8 pattern wafers of the lot of pattern wafers are sequentially polished on the first platen using the HSS pad for different polish time. Removal amount of each of the polished 3-8 pattern wafers is in-line measured and calculated to output a substantial linear plot or fitting curve of removal amount vs. polish time thereof. Based on the substantially linear fitting curve established by the foregoing 3-8 pattern wafers, the rest of the pattern wafers of the same lot as the foregoing 3-8 pattern wafers are sequentially polished on the first platen to reach a target thickness of remaining said first dielectric layer on each said pattern wafer.

In still another aspect, the present invention provides a method for controlling hybrid chemical mechanical polishing (CMP) process including providing a hybrid CMP system including at least a first platen and a second platen, wherein two different types of polish pads are mounted on the first platen and second platen, respectively. A lot of pattern wafers to be polished is prepared, wherein each pattern wafer has patterned features thereon, and a first dielectric layer disposed over a second dielectric layer and the patterned features. At least three foregoing pattern wafers of the lot of pattern wafers are polished on the first platen to remove different amount of the first dielectric layer from each said foregoing pattern wafer. Removal amount of each said foregoing pattern wafer is measured and calculated to output a first feedback fitting curve of removal amount vs. polish time thereof. The foregoing pattern wafers of the lot of pattern wafers are sequentially polished on the second platen to remove different amount of the first dielectric layer from each said foregoing pattern wafer. Removal amount of each said foregoing pattern wafer are measured and calculated to output a second feedback linear fitting curve of removal amount vs. polish time thereof. Based on the first feedback fitting curve, the rest of the pattern wafers of the same lot as said foregoing pattern wafers are sequentially polished on the first platen to reach a target thickness of remaining said first dielectric layer on each said pattern wafer. Based on the second feedback fitting curve, the rest of the pattern wafers of the same lot are sequentially polished on the second platen to remove remaining said first dielectric layer from each said pattern wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a plot showing the removal amount of trench fill oxide vs. polish time with respect to a HSS pad for a hybrid CMP process;

FIGS. 2-4 are schematic, cross-sectional diagrams illustrating one embodiment of a polishing process utilizing a three-platen hybrid CMP system containing a HSS pad on the first platen and a FA pad on the second platen;

FIG. 5 is a flow chart illustrating a method of controlling a target film thickness in an STI CMP process in accordance with one preferred embodiment of this invention;

FIG. 6 is an exemplary fitting curve of removal amount vs. polish time that is established according to the foregoing 3-8 pattern wafers polished by the first platen; and

FIG. 7 is a flow chart illustrating a method of controlling a target film thickness in a CMP process in accordance with another preferred embodiment of this invention.

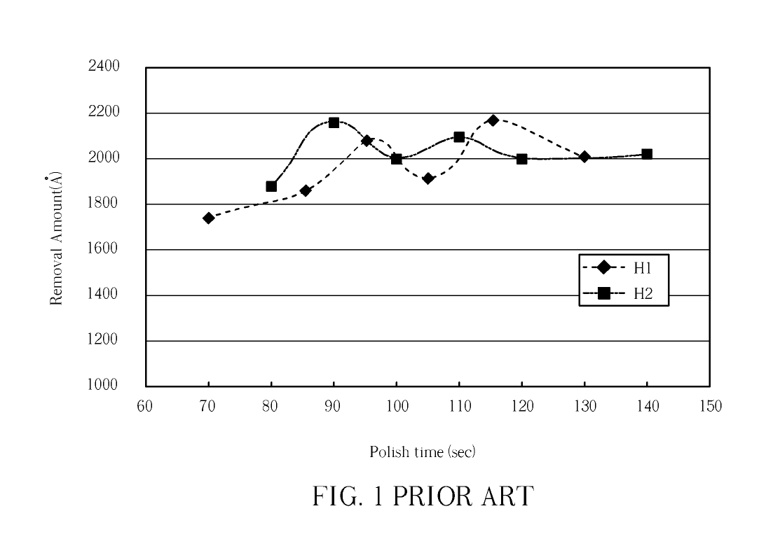

### DETAILED DESCRIPTION

In general, aspects of the invention provide methods for planarizing a substrate surface with reduced or minimal defects in surface topography. The invention will be described below in reference to a planarizing process for the removal of dielectric material from a substrate surface by chemical mechanical polishing (CMP) technique.

The CMP processes described herein may be performed by chemical mechanical polishing processing equipment containing two or three platens, such as the Reflexion™ polishing system, the Mirra™ polishing system, and the Mirra™ Mesa™ polishing system, all of which are available from Applied Materials, Inc., of Santa Clara, Calif. Hereinafter, a hybrid CMP system broadly refers to a CMP tool comprising the use of two different type of polish pads such as a high selectivity slurry (HSS) pad and a fixed-abrasive (FA) pad that are mounted on respective platens.

The present invention methods are provided for polishing a substrate containing at least two dielectric layers, such as silicon oxide and silicon nitride with at least one polishing step using a FA pad. The present invention method may be used to remove all, substantially all or a portion of the one or more dielectric layers. For example, a polishing step using a FA pad may be used to remove the topography, and/or residual dielectric material of a dielectric layer.

Topography is broadly defined herein as any projections or recessions formed at the exposed surface of a dielectric material, which provides a non-planar surface. For example, high-density plasma (HDP) chemical vapor deposition of silicon oxide may produce an exposed surface containing peaks of material extending above the bulk silicon oxide material.

Bulk dielectric material is broadly described herein as dielectric material deposited on the substrate in an amount more than sufficient to substantially fill features formed on the substrate surface. The bulk dielectric material may also be referred to as overfill material or blanket material.

Residual dielectric material is broadly defined as any bulk dielectric material remaining after one or more polishing process steps as well as the residue of any additional materials from layers disposed below the bulk dielectric material. Residual material may partially or completely cover the surface a substrate.

Substrates that may be polished by the process described herein may include shallow trench isolation structures formed in a series of dielectric layers, such as silicon oxide disposed over a silicon nitride pad layer.

The invention contemplates polishing dielectric materials conventionally employed in the manufacture of semiconductor devices, for example, silicon dioxide, silicon nitride, and silicon oxynitride.

The invention also contemplates the polishing of other dielectric materials, such as polysilicon, carbon doped silicon carbide, phosphorus-doped silicon glass (PSG), boron-phosphorus-doped silicon glass (BPSG), and silicon dioxide derived from tetraethyl orthosilicate (TEOS), high density plasma chemical vapor deposition (HDP-CVD) silicon oxides (HDP oxides), silane by plasma enhanced chemical vapor deposition (PECVD) can be employed, and combinations thereof.

In one embodiment of a polishing process, a substrate having a first dielectric material, such as silicon oxide, disposed on a second dielectric material, such as silicon nitride, may be first polished with a first polishing composition and an abrasive-free polishing pad to substantially remove the bulk of the first dielectric material, and then be polished with a second polishing composition and a FA pad to remove the remaining first dielectric material disposed on the substrate surface.

An example of an abrasive-free polishing pad is the IC-1000 polishing article commercially available from Rodel Inc., of Phoenix Ariz. The FA pad may include a hard resin fixed-abrasive web, for example, SWR-159 or SWR-521, commercially available from 3M of Minneapolis, Minn. One example of a polishing composition for use with FA pads is a proline or I-proline available from Applied Materials, Inc.

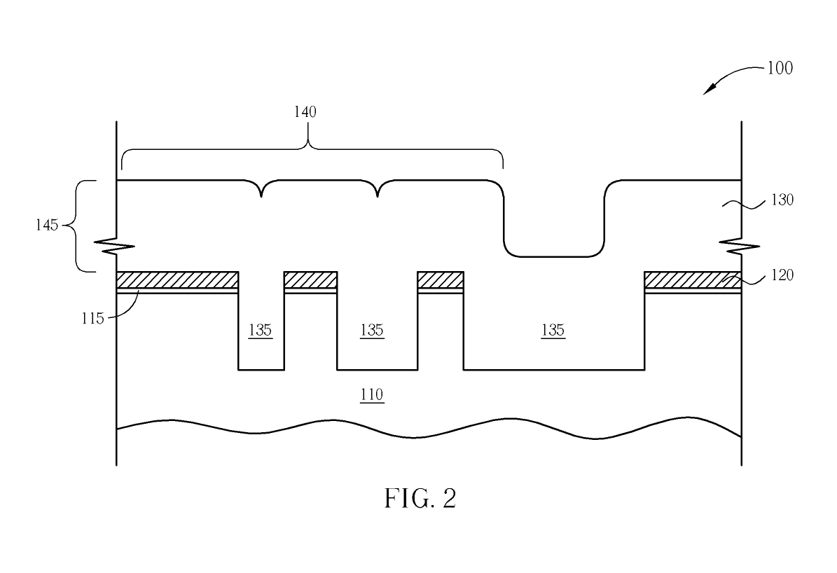

FIGS. 2-4 are schematic, cross-sectional diagrams illustrating one embodiment of a STI CMP process utilizing a three-platen hybrid CMP system containing a HSS pad mounted on the first platen and a FA pad mounted on the second platen.

As shown in FIG. 2, a substrate 100 having a patterned feature definitions 135 formed in a substrate layer 110, a pad oxide layer 115, and a pad nitride layer 120, is subjected to a bulk deposition of a dielectric fill material 130 on the substrate surface in a sufficient amount to fill features definitions 135. The dielectric fill material is a first dielectric material, such as HDP oxide, and the pad nitride layer 120 is a second dielectric material.

The deposited dielectric fill material 130 generally has an excess material deposition 145 of bulk dielectric material, that has an uneven surface topography 140 with peak and recesses typically formed over feature definitions 135 having varying widths.

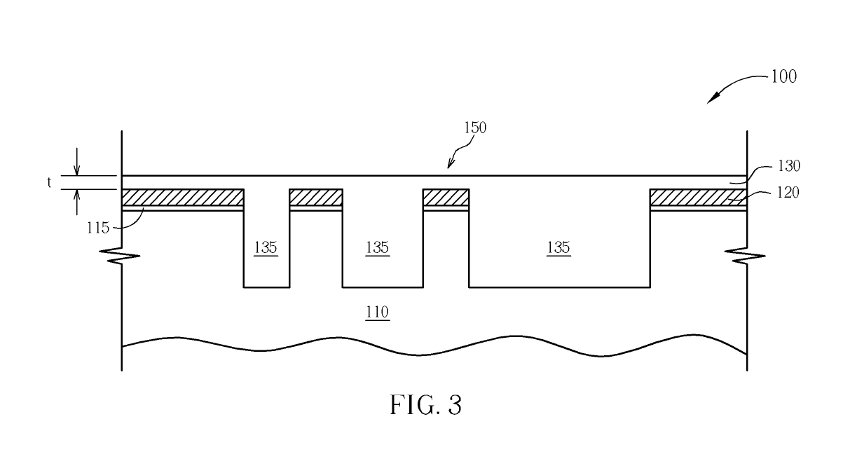

As shown in FIG. 3, dielectric fill material 130 is then polished on a first platen using a HSS pad and high selectivity slurry compositions dispensed thereon. At this stage, the bulk of the dielectric fill material 130 over the pad nitride layer 120 is removed. The remaining dielectric fill material 130 has a thickness t (i.e., incoming oxide thickness for the FA pad) and a substantially even surface 150.

As previously mentioned, it is critical to control the incoming oxide thickness t before the wafer is transferred to the second platen or the FA pad. The incoming oxide thickness control is particularly important for 300 mm FA web polish because so-called fast-band problem occurs resulting in narrow polish time window of the FA pad. Long polish time will lead to silicon nitride loss in fast-band areas, while short polish time will lead to residual oxide on non-fast band areas.

According to this invention, t is preferably between 200 and 250 angstroms.

The high-selectivity slurry compositions generally have a selectivity of silicon oxide to silicon nitride of greater than about 5:1, and preferably have a selectivity of about 30:1 or greater. The high selectivity compositions may include compositions having abrasive solutions, additives, and solvent. The abrasive solutions, additives, and solvent may be a ratio of X:Y:Z, with X=1 to 20, Y=0 to 20, and Z=0 to 20.

The abrasive solutions may contain between about 10 weight percent (wt. %) and about 30 wt. % of silica abrasive particles or between about 0.5 weight percent (wt. %) and about 5 wt. % of ceria abrasive particles. An example of an abrasive particle is ceria with a particle size of about 300 nm or less in size.

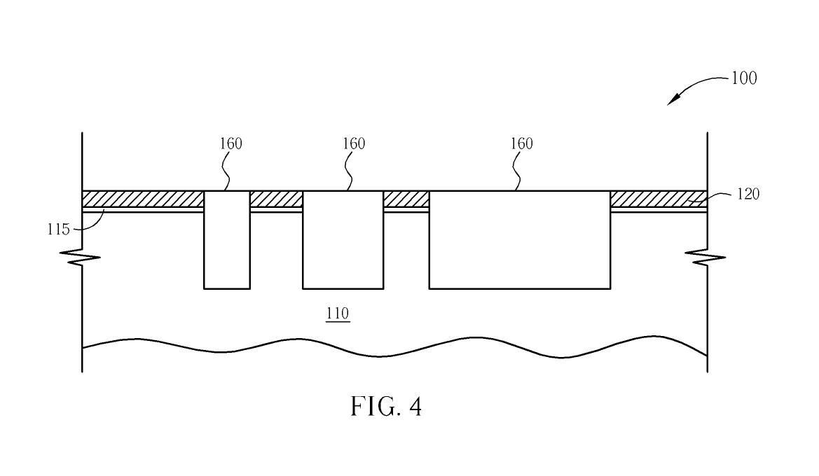

As shown in FIG. 4, the remaining dielectric fill material 130 is then polished on a second platen using a FA pad and abrasive-free slurry compositions dispensed thereon to form a planarized surface with isolated features 160. Any residual dielectric material on the pad nitride layer 120 may be removed in a third polishing processing step by polishing the wafer with a third platen with a buffing pad.

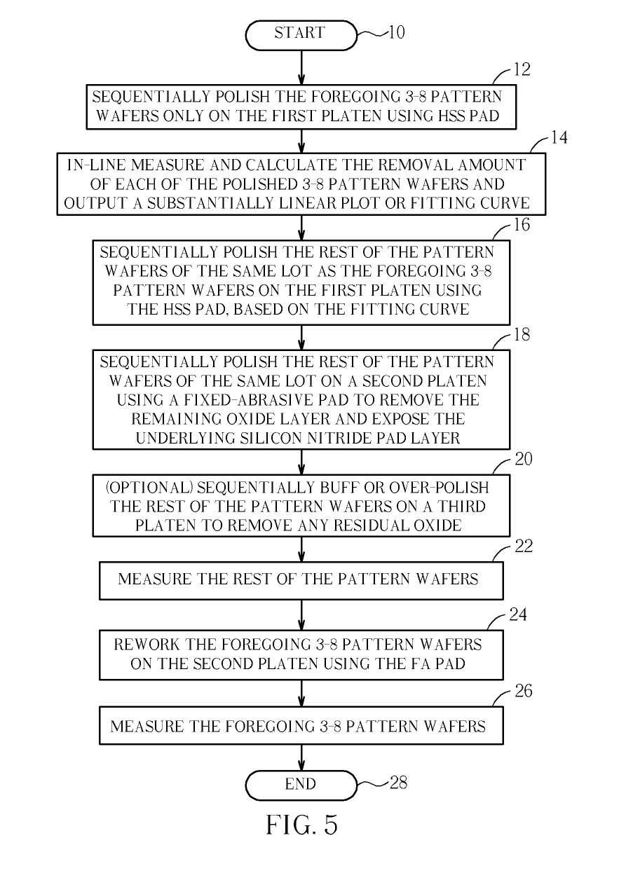

Please refer to FIG. 5. FIG. 5 is a flow chart illustrating a method of controlling a target film thickness in a CMP process in accordance with one preferred embodiment of this invention. It is one feature of this invention that a linear fitting curve of removal amount vs. polish time with respect to a HSS pad mounted on the first platen is established in-line by polishing the foregoing 3-8 pattern wafers of each lot (ordinarily 25 wafers per lot) to be processed without using a blanket wafer.

As shown in FIG. 5, the method includes the steps as follows:

Step 10: start;

Step 12: sequentially polish the foregoing 3-8 pattern wafers only on the first platen using HSS pad, each of which is polished for different polish time, for example, 70 seconds, 80 seconds and 90 seconds for the first, second and third pattern wafers, respectively, and so on;

Step 14: in-line measure and calculate the removal amount of each of the polished 3-8 pattern wafers and output a substantially linear plot or fitting curve of removal amount vs. polish time thereof (the removal amount is the original thickness of oxide before polishing subtracts the measured thickness of the remaining oxide);

Step 16: sequentially polish the rest of the pattern wafers of the same lot as the foregoing 3-8 pattern wafers on the first platen using the HSS pad, based on the fitting curve of removal amount vs. polish time established by the foregoing 3-8 pattern wafers;

Step 18: sequentially polish the rest of the pattern wafers of the same lot on a second platen using a fixed-abrasive pad to remove the remaining oxide layer and expose the underlying silicon nitride pad layer;

Step 20: (optional): sequentially buff or over-polish the rest of the pattern wafers on a third platen to remove any residual oxide;

Step 22: measure the rest of the pattern wafers;

Step 24: rework the foregoing 3-8 pattern wafers on the second platen using the FA pad;

Step 26: measure the foregoing 3-8 pattern wafers; and

Step 28: end.

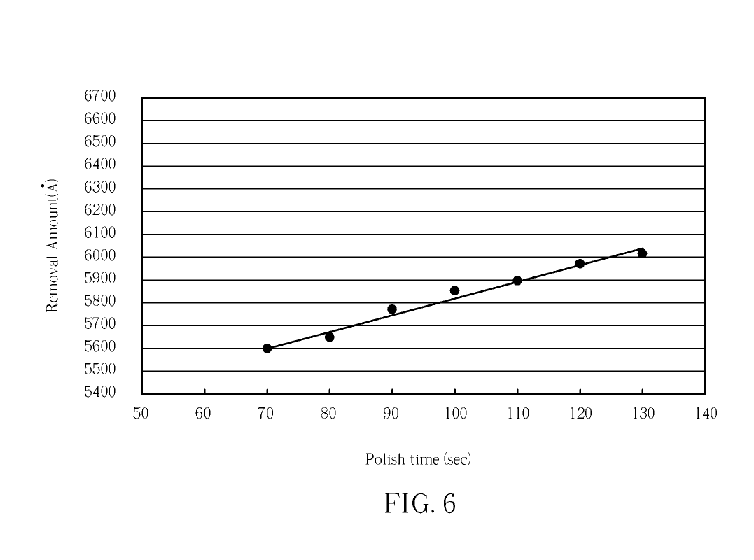

An exemplary linear fitting curve of removal amount vs. polish time that is established according to the foregoing 3-8 pattern wafers polished by the first platen is shown in FIG. 6. Feedback polish rate information (slope of the fitted linear curve) of the HSS pad can be calculated from this plot. According tot the feedback polish rate information, the rest of the pattern wafers of the same lot as the foregoing 3-8 pattern wafers can then be polished under time mode, end-point mode or removal rate mode to achieve the target incoming oxide thickness.

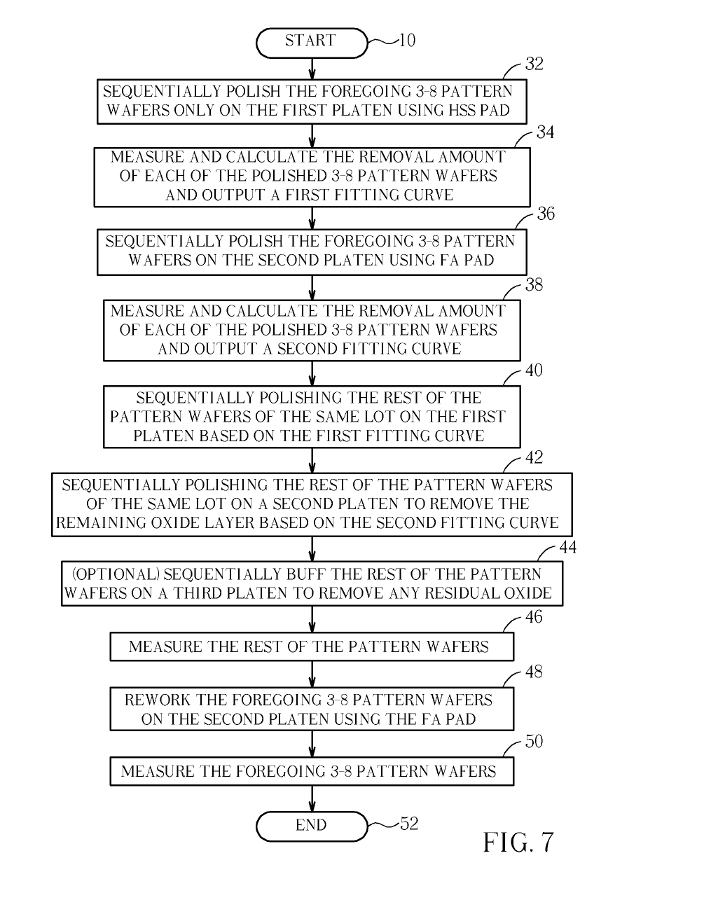

Please refer to FIG. 7. FIG. 7 is a flow chart illustrating a method of controlling a target film thickness in a CMP process in accordance with another preferred embodiment of this invention. It is one feature of this invention that a linear plot of removal amount vs. polish time of a HSS pad on the first platen is established in-line by polishing the foregoing 3-8 pattern wafers of each lot of product wafers (ordinarily 25 wafers per lot) to be processed without using a blanket wafer.

As shown in FIG. 7, the method includes the steps as follows:

Step 30: start;

Step 32: sequentially polish the foregoing 3-8 pattern wafers only on the first platen using HSS pad, which are polished for different polish time;

Step 34: measure and calculate the removal amount of each of the polished 3-8 pattern wafers and output a first fitting curve of removal amount vs. polish time thereof;

Step 36: sequentially polish the foregoing 3-8 pattern wafers on the second platen using FA pad, which are polished for different polish time;

Step 38: in-line measure and calculate the removal amount of each of the polished 3-8 pattern wafers and output a second fitting curve of removal amount vs. polish time thereof;

Step 40: sequentially polishing the rest of the pattern wafers of the same lot on the first platen based on the first fitting curve established by the foregoing 3-8 pattern wafers;

Step 42: sequentially polishing the rest of the pattern wafers of the same lot on a second platen to remove the remaining oxide layer based on the second fitting curve;

Step 44: (optional): sequentially buff or over-polish the rest of the pattern wafers on a third platen to remove any residual oxide;

Step 46: measure the rest of the pattern wafers;

Step 48: rework the foregoing 3-8 pattern wafers on the second platen using the FA pad;

Step 50: measure the foregoing 3-8 pattern wafers; and

Step 52: end.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for controlling hybrid chemical mechanical polishing (CMP) process, comprising:
providing a hybrid CMP system including at least a first platen and a second platen, wherein two different types of polish pads are mounted on the first platen and second platen, respectively;
providing a lot of pattern wafers to be polished, wherein each pattern wafer has patterned features thereon, and a first dielectric layer disposed over a second dielectric layer and the patterned features;
sequentially polishing at least three foregoing pattern wafers of the lot of pattern wafers on the first platen to remove different amount of the first dielectric layer from each said foregoing pattern wafer;
in-line measuring and calculating removal amount of each said foregoing pattern wafer to output a feedback fitting curve of removal amount vs. polish time thereof; and
based on the feedback fitting curve established by said foregoing pattern wafers, sequentially polishing rest of the pattern wafers of the same lot as said foregoing pattern wafers on the first platen to reach a target thickness of remaining said first dielectric layer on each said pattern wafer.

2. The method according to claim 1 wherein after polishing the rest of the pattern wafers on the first platen, the method further comprises the following step:
sequentially polishing the rest of the pattern wafers of the same lot on the second platen to remove the remaining said first dielectric layer and expose the second dielectric layer.

3. The method according to claim 2 wherein after polishing the rest of the pattern wafers on the second platen, the method further comprises the following step:
sequentially buffing the rest of the pattern wafers on a third platen to remove any residual said first dielectric layer from surface of the second dielectric layer.

4. The method according to claim 1 wherein the two different types of polish pads are high-selectivity slurry (HSS) pad and fixed-abrasive (FA) pad.

5. The method according to claim 1 wherein the patterned features comprise shallow trench isolation (STI) structures.

6. The method according to claim 1 wherein the first dielectric layer comprises silicon oxide.

7. The method according to claim 1 wherein the second dielectric layer comprises silicon nitride.

8. The method according to claim 1 wherein the rest of the pattern wafers of the same lot as said foregoing pattern wafers are polished on the first platen under time mode.

9. The method according to claim 1 wherein the rest of the pattern wafers of the same lot as said foregoing pattern wafers are polished on the first platen under removal rate mode.

10. The method according to claim 1 wherein the target thickness of remaining said first dielectric layer on each said pattern wafer is between 200 and 250 angstroms.

11. A method for controlling hybrid chemical mechanical polishing (CMP) process, comprising:
providing a hybrid CMP system including at least a first platen and a second platen, wherein a high-selectivity slurry (HSS) pad and a fixed-abrasive (FA) pad are mounted on the first platen and second platen, respectively;
providing a lot of pattern wafers to be polished, wherein each pattern wafer has patterned features thereon, and a first dielectric layer disposed over a second dielectric layer and the patterned features;
sequentially polishing the foregoing 3-8 pattern wafers of the lot of pattern wafers on the first platen using the HSS pad for different polish time;
in-line measuring and calculating removal amount of each of the polished 3-8 pattern wafers and output a feedback fitting curve of removal amount vs. polish time thereof;
based on the feedback fitting curve established by the foregoing 3-8 pattern wafers, sequentially polishing rest of the pattern wafers of the same lot as the foregoing 3-8 pattern wafers on the first platen to reach a target thickness of remaining said first dielectric layer on each said pattern wafer.

12. The method according to claim 11 wherein after polishing the rest of the pattern wafers on the first platen, the method further comprises the following step:
sequentially polishing the rest of the pattern wafers of the same lot on the second platen to remove the remaining said first dielectric layer and expose the second dielectric layer.

13. The method according to claim 12 wherein after polishing the rest of the pattern wafers on the second platen, the method further comprises the following step:
sequentially buffing the rest of the pattern wafers on a third platen to remove any residual said first dielectric layer from surface of the second dielectric layer.

14. The method according to claim 11 wherein the patterned features comprise shallow trench isolation (STI) structures.

15. The method according to claim 11 wherein the first dielectric layer comprises silicon oxide.

16. The method according to claim 11 wherein the second dielectric layer comprises silicon nitride.

17. The method according to claim 11 wherein the rest of the pattern wafers of the same lot as said foregoing pattern wafers are polished on the first platen under time mode.

18. The method according to claim 11 wherein the rest of the pattern wafers of the same lot as said foregoing pattern wafers are polished on the first platen under removal rate mode.

19. The method according to claim 11 wherein the target thickness of remaining said first dielectric layer on each said pattern wafer is between 200 and 250 angstroms.

20. A method for controlling hybrid chemical mechanical polishing (CMP) process, comprising:
providing a hybrid CMP system including at least a first platen and a second platen, wherein two different types of polish pads are mounted on the first platen and second platen, respectively;
providing a lot of pattern wafers to be polished, wherein each pattern wafer has patterned features thereon, and a first dielectric layer disposed over a second dielectric layer and the patterned features;
sequentially polishing at least three foregoing pattern wafers of the lot of pattern wafers on the first platen to remove different amount of the first dielectric layer from each said foregoing pattern wafer;
measuring and calculating removal amount of each said foregoing pattern wafer to output a first feedback fitting curve of removal amount vs. polish time thereof;
sequentially polishing the foregoing pattern wafers of the lot of pattern wafers on the second platen to remove different amount of the first dielectric layer from each said foregoing pattern wafer;
measuring and calculating removal amount of each said foregoing pattern wafer to output a second feedback linear fitting curve of removal amount vs. polish time thereof;
based on the first feedback fitting curve, sequentially polishing rest of the pattern wafers of the same lot as said foregoing pattern wafers on the first platen to reach a target thickness of remaining said first dielectric layer on each said pattern wafer; and
based on the second feedback fitting curve, sequentially polishing the rest of the pattern wafers of the same lot on the second platen to remove remaining said first dielectric layer from each said pattern wafer.

21. The method according to claim 20 wherein after polishing the rest of the pattern wafers on the second platen, the method further comprises the following step:
sequentially buffing the rest of the pattern wafers on a third platen to remove any residual said first dielectric layer from surface of the second dielectric layer.

22. The method according to claim 20 wherein the two different types of polish pads are high-selectivity slurry (HSS) pad and fixed-abrasive (FA) pad.

23. The method according to claim 20 wherein the patterned features comprise shallow trench isolation (STI) structures.

24. The method according to claim 20 wherein the first dielectric layer comprises silicon oxide.

25. The method according to claim 20 wherein the second dielectric layer comprises silicon nitride.

26. The method according to claim 20 wherein the rest of the pattern wafers of the same lot as said foregoing pattern wafers are polished on the first platen under time mode.

27. The method according to claim 20 wherein the rest of the pattern wafers of the same lot as said foregoing pattern wafers are polished on the first platen under removal rate mode.

28. The method according to claim 20 wherein the target thickness of remaining said first dielectric layer on each said pattern wafer is between 200 and 250 angstroms.
